(19) United States
(12) Patent Application Publication
(10) Pub. No.: US 2007/0157464 A1
(43) Pub. Date: Jul. 12, 2007

(54) Soldering driving elements in LCD panels

(75) Inventors: Jae-Woo Jeon, Gyeonggi-do (KR); Hyun-Gyu Choi, Gyeonggi-do (KR); Hee-Young Park, Gyeonggi-do (KR); Ho-Jeong Kang, Gyeonggi-do (KR)

Correspondence Address: MACPHERSON KWOK CHEN & HEID LLP, 2033 GATEWAY PLACE, SUITE 400, SAN JOSE, CA, 95110, US

(73) Assignee: Samsung Electronics Co., Ltd., Suwon-si (KR)

(21) Appl. No.: 11/544,339

(22) Filed: Oct. 5, 2006

(30) Foreign Application Priority Data
Jan. 6, 2006 (KR) 2006-1876

(51) Int. Cl. H05K 3/34; B23K 37/00

(52) U.S. Cl. 29/840; 29/742; 228/4.1; 228/179.1

(57) ABSTRACT

An apparatus and method for soldering an LED driving element to an LCD panel includes a panel holding unit, a rotating unit and a soldering unit. The panel holding unit holds the display panel. The rotating unit supports the panel holding unit at initial radial and angular positions relative to a center of rotation of the rotating unit and rotates the holding unit in a horizontal plane about the center of rotation to selected angular positions relative thereto. The soldering unit is disposed above the rotating unit at the initial radial position and at a first angular position relative to initial angular position of the holding unit, and is operable to solder the driving element of the display panel held by the panel holding unit when the rotating unit rotates the panel holding unit to the first angular position. The apparatus and method provide improved display panel productivity.

### RELATED APPLICATIONS

This application claims priority of Korean Patent Application No. 2006-01876, filed Jan. 6, 2006, the entire disclosure of which is incorporated herein by reference.

### BACKGROUND

This invention relates to methods and apparatus for soldering light emitting diode (LED) driving elements in liquid crystal display (LCD) panels to improve panel productivity.

In general, LCDs are flat panel display devices that display an image using the electro-optical characteristics of liquid crystals. LCDs provide many features and advantages relative to other types of display devices, such as a thinner display panel, lighter weight, lower power consumption, lower driving voltages, and others. Accordingly, LCDs have been widely adopted as the display device of choice in a number of fields, e.g., large screen television sets, computer monitors, mobile communication terminals, and the like.

An LCD includes an LCD panel and a backlight assembly. The LCD panel displays the image using the light provided to it by the backlight assembly. In order to decrease the size and weight of the backlight assembly, the backlight assembly can comprise a number of LEDs having a high luminance. Such backlight assemblies generally include a driving element for driving the LEDs. The driving element is typically soldered to a flexible circuit board in the display panel.

Conventionally, the driving elements are manually soldered to the flexible circuit board by a factory worker. However, this technique is slow and substantially increases display manufacturing time. Further, the worker is subject to illnesses caused by long term exposure to the lead used in the solder.

### BRIEF SUMMARY

In accordance with the exemplary embodiments thereof described herein, the present invention provides apparatus and methods for soldering LED driving elements in an LCD display panel that improve display panel manufacturing productivity and reduce the potentially harmful exposure of factory workers to lead.

In one exemplary embodiment, an apparatus for soldering driving elements in display panel comprises a panel holding unit, a rotating unit and a soldering unit. The apparatus may further include a flux supplying unit and a panel transporting unit. The panel holding unit holds the display panel during the soldering operations. A rotating unit supports the panel holding unit at initial radial and angular positions relative to a center of rotation of the rotating unit, and is operable to rotate the holding unit in a horizontal plane about the center of rotation to selected angular positions relative to the initial angular position.

The soldering unit is disposed above the rotating unit at the initial radial position and at a first angular position relative to the initial angular position of the panel holding unit, and is operable to solder the driving element of the display panel held by the panel holding unit when the panel holding unit is rotated to the first angular position by the rotating unit.

The flux applying unit is disposed above the rotating unit at the initial radial position and at a second angular position relative to the initial angular position of the panel holding unit, and is operable to apply flux to the driving element of the display panel when the panel holding unit is rotated to the second angular position by the rotating unit.

The panel transporting unit is disposed above the rotating unit at the initial radial position and at a third angular position relative to the initial angular position of the panel holding unit, and is operable to transport the display panel to a conveyor.

In accordance with another aspect of the present invention, an exemplary embodiment of a method for soldering a display panel using the novel apparatus comprises loading the display panel onto the panel holding unit, supporting the panel holding unit on the upper surface the rotating unit, rotating the panel holding unit with the rotating unit in a horizontal plane about a center of rotation of the rotating unit and to a position below the soldering unit, and soldering the driving element to the display panel with the soldering unit. After the driving element is soldered, the soldered display panel is transported to a conveyor.

In accordance with another exemplary method, before the driving element is soldered, the panel holding unit is first rotated to a position below the flux applying unit and flux is applied to the driving element.

In according with the present invention, soldering of the display driving elements is not manually effected by a factory worker, but instead, by the automated soldering apparatus of the invention. As a result, display panel productivity is substantially increased, and the health risk to workers due to long term exposure to lead is substantially reduced.

A better understanding of the above and many other features and advantages of the LCD LED driving element soldering methods and apparatus of the invention may be obtained from a consideration of the detailed description of some exemplary embodiments thereof below, particularly if such consideration is made in conjunction with the appended drawings, wherein like reference numerals are used to identify like elements illustrated in one or more of the figures thereof.

### BRIEF DESCRIPTION OF THE DRAWINGS

FIG. 1 is a partial upper front side perspective view of an exemplary embodiment of an apparatus for soldering LED driving elements in an LCD panel in accordance with the present invention;

FIG. 2 is a partial top plan view of the exemplary soldering apparatus of FIG. 1;

FIG. 3 is a partial upper front side perspective view a holding unit of the apparatus;

FIG. 4 is a partial perspective view of a flux application unit of the apparatus;

FIG. 5 is a partial perspective view of a soldering unit of the apparatus; and,

FIG. 6 is a partial upper front perspective view of a panel transporting unit of the apparatus.

### DETAILED DESCRIPTION

The invention is described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. In the drawings, the size and relative sizes of layers and regions may be exaggerated for clarity. It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numbers refer to like elements throughout. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Embodiments of the invention are described herein with reference to cross-section illustrations that are schematic illustrations of idealized embodiments (and intermediate structures) of the invention. As such, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, the present invention will be described in detail with reference to the accompanying drawings.

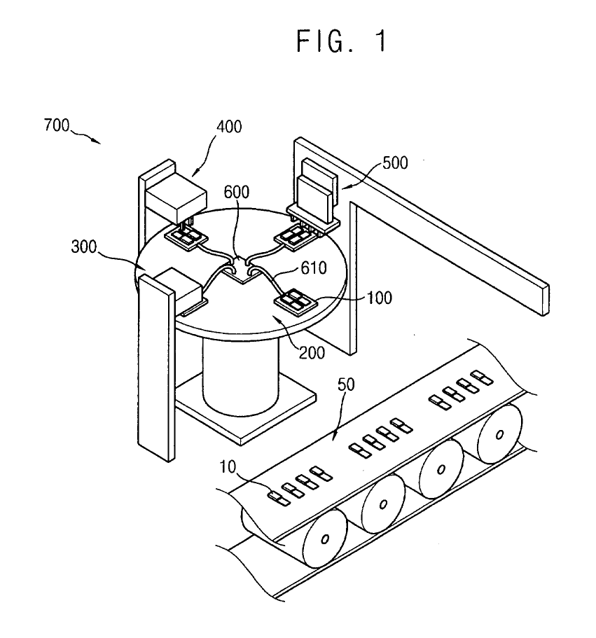

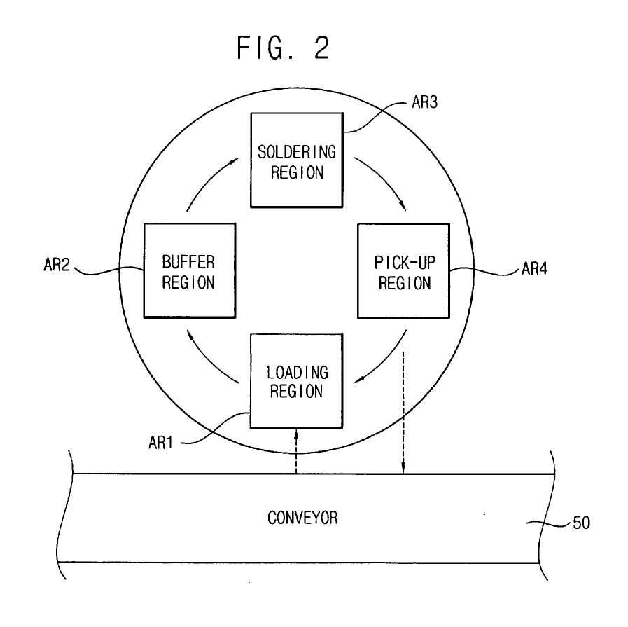

FIG. 1 is a partial upper front side perspective view of an exemplary embodiment of an apparatus 700 for soldering LED driving elements to an LCD panel in accordance with the present invention, and FIG. 2 is a partial top plan view thereof. As illustrated in FIGS. 1 and 2, the exemplary soldering apparatus 700 includes a plurality of panel holding unit 100, a rotating unit 200, a flux applying unit 300, a soldering unit 400, a panel transporting unit 500 and a pressurized air supply unit 600. These elements are first described briefly, and then in more detail with reference to accompanying drawings.

The panel holding units 100 are each operable to hold one or more LCD panels 10 in a generally horizontal position, for example, by means of pressurized air supplied by the pressurized air supply unit 600. In the particular exemplary embodiment of FIG. 1, each panel holding unit 100 holds four display panels 10.

The panel holding units 100 are disposed on the upper surface of the rotating unit 200 and at a selected radial distance from the center of rotation thereof. In the exemplary embodiment of FIG. 1, four panel holding units 100 are arranged on the rotating unit 200 such that they form the corners of a generally square pattern. When the four panel holding units 100 are thus arranged in the square pattern illustrated, each of the panel holding units 100 may be rotated in a horizontal plane to selected angular positions about the center of the rotating unit 200. As illustrated in the schematic top plan view of FIG. 2, the soldering apparatus 700 includes a loading region AR1, a buffer or fluxing region AR2, a soldering region AR3 and a pick-up region AR4. Each of the loading, buffer, soldering and pick-up regions AR1, AR2, AR3, and AR4 correspond to a respective one of the angular positions of the four panel holding units 100.

The rotating unit 200 is operable to support the panel holding units 100 and to rotate them simultaneously in a substantially horizontal plane, for example, in a clockwise direction, as indicated by the arrows shown in FIG. 2. In particular, the rotating unit 200 functions to rotate the panel holding units 100 to selected angular positions such that they are consecutively disposed directly below respective ones of the flux unit 300, the soldering unit 400 and the transporting unit. For example, the rotating unit 200 may rotate the four panel holding units 100 in 90° increments about the center of rotation of the rotating unit 200. In an alternative embodiment, the rotating unit may support only three panel holding units, and rotate them in angular increments of 120° about the center of the rotating unit, or alternatively, the rotating unit may support only two panel holding units, and rotate them in 180° increments about the center of the rotating unit.

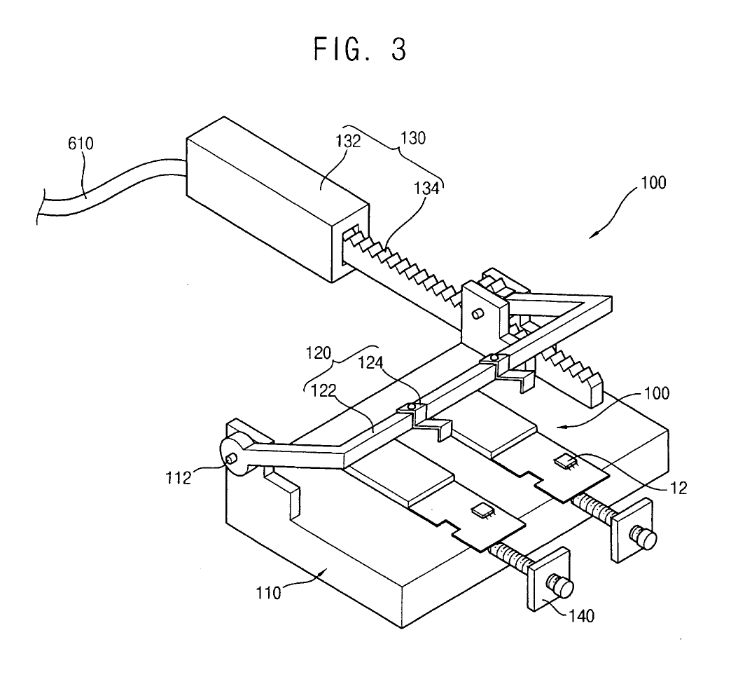

As illustrated in FIGS. 1 and 2, the flux applying unit 300 is disposed in the buffer region AR2 of the apparatus 700, and is operable to apply a soldering flux to the LED driving elements 12 of the display panels 10 (see FIG. 3) that are rotated into position therebelow. The display panels 100 may comprise, for example, display panels 10 for mobile communication terminals, and the driving elements 12 may be disposed on a flexible circuit board that is disposed on the display panel 10.

The soldering unit 400 is disposed in the soldering region AR3 of the apparatus 700, and is operable to solder the connecting leads or terminals of the driving element 12 to the flexible circuit board of the display panel 10 with a solder alloy.

The panel transporting unit 500 is disposed in the pickup region AR4 of the apparatus 700, and as discussed below, a portion of the panel transporting unit 500 is arranged to extend above the conveyor 50. The panel transporting unit 500 is operable to pick up the display panels 10 held by the panel holding units 100 on the rotating unit 200 and to transport them back to the conveyor 50.

In the exemplary embodiment of FIG. 1, the pressurized air supply unit 600 is disposed at the center of the rotating unit 100, but may be placed at other locations in the apparatus, as well. The pressurized air supply unit 600 supplies a pressurized air to each of the panel holding units 500 through, e.g., pressurized air supply lines 610, to enable them to hold the respective display panels 10.

FIG. 3 is a partial upper front side perspective view the holding unit 100 of the apparatus 700. As illustrated in FIG. 3, the panel holding unit 100 includes a main body 110, a rotating part 120, a torque generating part 130 and one or more holding parts 140. The main body 110 supports the display panels 10. In the particular embodiment illustrated in FIG. 3, the main body 110 is shown supporting two display panels 10, but in other embodiments, may support greater or fewer numbers of panels. In the particular embodiment illustrated, two coaxial shafts 112 protrude laterally from opposite sides of the main body 110. The rotating part 120 is rotatably mounted on the shafts 112 for rotation about the common axes thereof and toward and away from the main body 110 so as to fix and release the display panel 10 to and from the main body 110, respectively. The rotating part 120 includes a rotating cross bar 122 and one or more clamps 124 that press down on the display panel 10 when the rotating part 120 is rotated down toward the main body 110.

As illustrated in FIG. 3, the cross bar 122 extends generally parallel to the upper surface of the main body 110, and includes a pair of extension arms disposed perpendicular thereto at the opposite ends thereof, the respective ends of which are mounted on the shafts 112 of the main body 110. In the particular exemplary embodiment illustrated in FIG. 3, each of the respective ends of the extension arms comprises an annular mounting lug that mounts on a respective one of the two shafts 112 of the main body 110. A spur gear is formed on the circumferential surface of the right lug to act as the pinion of a rack-and-pinion arrangement, as described in more detail below. Thus, the cross bar 122 is arranged to rotate on the two shafts 112 to which the mounting lugs are respectively mounted and relative to the main body in response to, for example, a torque applied thereto through the spur gear.

The clamps 124 are disposed on the cross bar 122 for conjoint rotation therewith. In the exemplary embodiment illustrated, each of the clamps 124 comprises a bent plate having three right-angled bends. An end portion of each of the clamps 124 presses against the flexible circuit board of a respective one of the display panels 100. In particular, the end portion of the clamp 124 presses against a portion of the display panel 100 adjacent to the LED driving element 12 that is to be soldered by the apparatus 700. When the two display panels 10 are appropriately positioned on the main body 110, the two clamps 124 are spaced apart from each other on the cross bar 122, and each respectively engages a corresponding one of the LCD panels 10. The clamps 124 are preferably made of an elastic material so that they recover their original shape after being defected. For example, the clamps 124 may be made of a spring steel that has a high elasticity, and is resistant to impact and fatigue. The elastic clamps 124 thus act to press against the respective display panels 10 such that the panels are securely held to and against the main body 110.

In the particular exemplary embodiment illustrated in FIG. 3, the torque generating part 130 comprises a pneumatic linear transducer 132 driving a geared rack 134, which is operable to generate a torque for rotating the cross arm 120 toward and away from the main body 110. However, in other possible embodiments, the torque generating part can comprise, e.g., a hydraulic or an electromagnetic transducer having a connecting rod coupled thereto. The torque generating part 130 causes the rack 134 to reciprocate in the longitudinal direction thereof, and responsively, the cross arm 120 to rotate up and down relative to the main body 110, depending on the direction of movement of the rack 134. In the exemplary embodiment of FIG. 3, the torque generating part 130 comprises a pressurized-gas-actuated cylinder 132 having a geared rack 134 coupled thereto. The cylinder 132 receives pressurized air from the pressurized air supply unit 600 through the pressure applying line 610, and the rack 134 is translated in the longitudinal direction of the rack and perpendicular to the cross bar 122 by pressurized air applied to the cylinder 132. The teeth of the rack 134, in turn, are engaged with the teeth of the gear formed on the mounting lug of the cross bar 122 such that, when the rack 134 reciprocates back and forth in the longitudinal direction, the cross bar 122 rotates up and down relative to the main body 110, and hence, relative to the display panels 10, to press them into place thereon.

The holding parts 140 are respectively coupled to the main body 110 by threaded shafts or screws, and are arranged so as to move in a horizontal direction relative toward the main body 110 so as to hold respective ones of the display panels 10 to the main body. In the particular exemplary embodiment illustrated, each of the holding parts 140 is coupled to the front end of the main body 110 by a threaded shaft in a spaced apart relationship such that, when the screw is turned, the holding part 140 presses against an end portion of a respective one of the display panels 10 such that the display panels 10 are thereby held to the main body 110. The length of the screws is adjustable to enable panels 10 of various sizes to be fixed to the main body 110. Additionally, if one of the clamps 124 of the rotating part 120 presses against a display panel 10 at an incorrect position thereon, the screw of the associated holding part 140 can be adjusted to correct the position of the display panel 10 relative to the clamp 124.

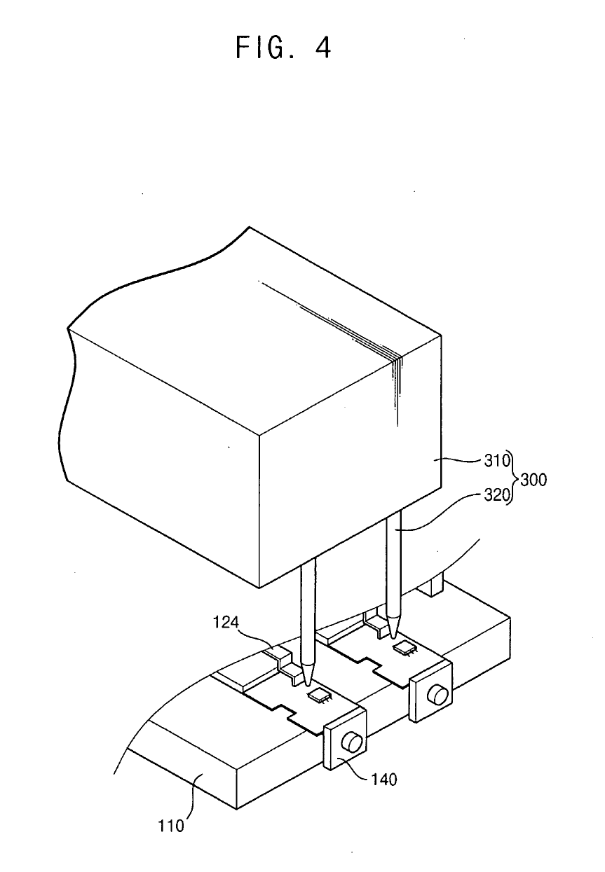

FIG. 4 is a partial perspective view of the flux applying unit 300 of the apparatus 700. Referring to FIG. 4, the flux applying unit 300 is operable to apply a metered amount of a soldering flux to the leads of the driving elements 12 of the respective display panels 10 held on the underlying panel holding unit 100.

The flux applying unit 300 includes a flux storage body 310 and a flux supplying part 320. The flux storage body 310 is disposed above the rotating unit 200 at the same radial distance from its center of rotation as the panel holding unit 100 and at a selected angular position relative thereto, and additionally, may be translatable in either or both of a vertical and a horizontal direction relative to the underlying display panels 100. The flux supplying part 320 protrudes downwardly from a lower surface of the flux storage body 310 to supply the driving elements 12 of the respective display panels 10 with flux. The flux supplying part 320 may be shaped like a pen. The flux is applied to the leads of the driving elements 12 of the display panels 10 by pressing the lower end of the flux supplying part 320 against the leads and then dispensing an appropriate amount of the flux onto the leads through an opening in the lower end.

When two display panels 10 are arranged on the main body 110, the flux unit 300 may include two flux supplying parts 320, and in general, the number of flux supplying parts 320 is the same as the number of the display panels 10 arranged on the main body 110.

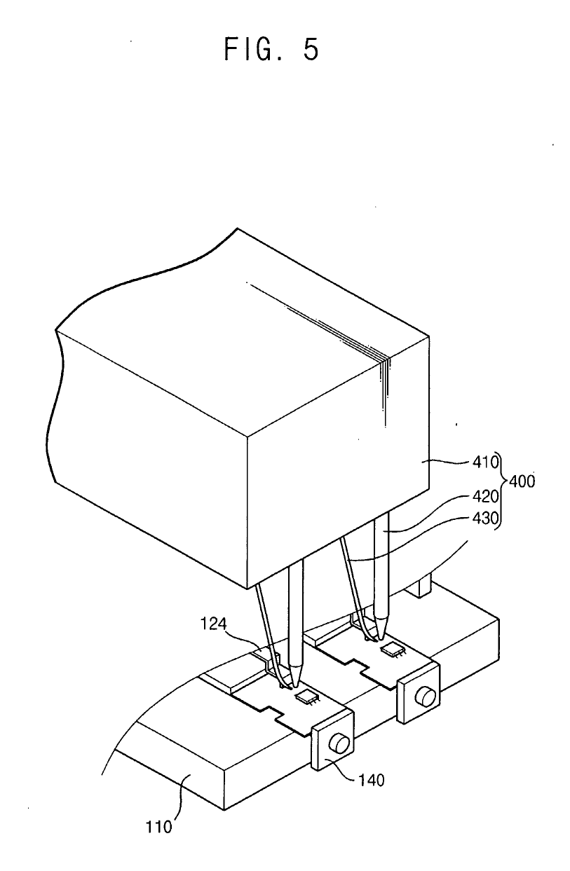

FIG. 5 is a partial perspective view of the soldering unit 400 of the exemplary apparatus 400. As illustrated in FIG. 5, the soldering unit 400 is operable to solder the respective driving elements 12 of the respective display panels 10 held on the respective underlying panel holding units 100. The soldering unit 400 includes a soldering body 410, a soldering part 420 and a solder supplying part 430.

The soldering body 410 is disposed above the rotating unit 200 at the same radial distance from its center of rotation as the panel holding unit 100 and at a selected angular position relative thereto. Additionally, the soldering body 410 may be translatable in either or both of a vertical and a horizontal direction relative to the underlying panels 10. The soldering part 420 protrudes from a lower surface of the soldering body 410 and is operable to solder the leads of the respective driving elements 12 of the underlying display panels 10 with solder. For example, the soldering part 420 is heated to a temperature of from between about 300° C. to about 380° C. to melt the solder so that the connecting leads or terminals of the relevant driving element 12 is soldered to the flexible circuit board of the underlying display panel 10. In the particular embodiment of FIG. 5, the soldering part 420 is shaped like a pen.

In the particular exemplary embodiment of FIG. 5, the soldering body 410 includes two depending soldering parts 420. Alternatively, only one soldering part 420 may depend from the soldering body 410 to improve soldering accuracy. When only one soldering part 420 is connected to the soldering body 410, the soldering unit 400 solders only one driving element 12 at a time, and is then transported to an adjacent driving element 12 to solder it, i.e., the soldering is effected sequentially.

The solder supplying part 430 protrudes downwardly from the lower surface of the soldering body 410, and is positioned adjacent to the soldering part 420. The solder supplying part 430 may, for example, feed, spray or otherwise dispense a selected amount of solder onto the connecting terminal of the driving element 12. The supplying part 430 receives the solder from an external solder storage unit (not illustrated). The number of the solder supplying parts 430 is, in general, the same as the number of the soldering parts 420.

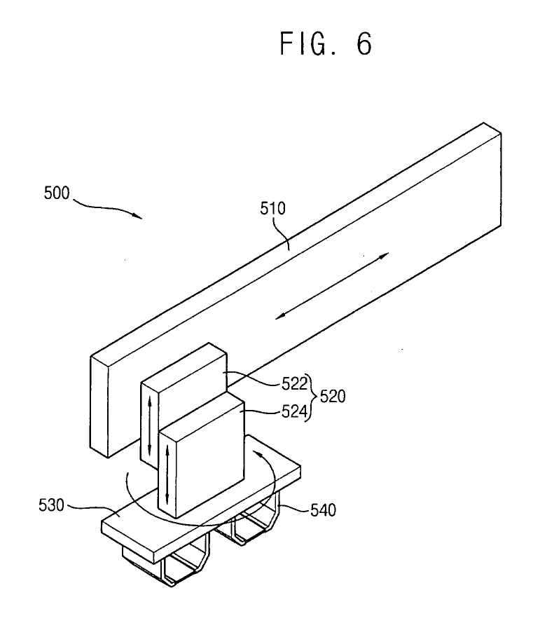

FIG. 6 is a partial upper front perspective view of a panel transporting unit 500 of the exemplary soldering apparatus 700. As illustrated in FIG. 6, the panel transporting unit 500 is operable to transport the display panels 10 held on the respective panel holding units 100 on the rotating unit 200 to the conveyor 50. The panel transporting unit 500 comprises a horizontal transporting portion 510, a vertical transporting portion 520, a rotational transporting portion 530 and a panel pickup portion 540.

The horizontal transporting portion 510 transports the display panels 10 in a horizontal direction parallel to the upper surface of the rotating unit 200. The horizontal transporting portion 510 may be actuated, for example, by pressurized air supplied to it by the pressurized air supply unit 600.

The vertical transporting portion 520 is coupled with the horizontal transporting portion 510 and operable to transport the display panels 10 in the vertical direction. The vertical transporting portion 510 may also be actuated with pressurized air. As illustrated in FIG. 6, the vertical transporting portion 520 includes first and second vertical transporters 522 and 524. The first vertical transporter 522 is coupled to the horizontal transporting portion 510 to transport the display panel 10 through a first vertical distance, and the second vertical transporter 524 is coupled to the first vertical transporting portion 522 to transport the display panel 10 through a second vertical distance. Thus, the vertical transporting portion 520 is arranged to transport the display panels 10 in the vertical direction by a distance that is equal to the sum of the first and second distances using the first and second vertical transporters 522 and 524.

As illustrated in FIGS. 1 and 6, the rotating unit 200 may be disposed at a different height than the conveyor 50. For example, the conveyor 50 may be disposed lower than the rotating unit 200, and the transporting portion is therefore provided with the first and second vertical transporters 522 and 524 to accommodate this difference in height. The rotational transporting portion 530, in turn, is coupled to the second vertical transporter 524 of the vertical transporting portion 520 to rotate the display panels 10 through a selected angle about a vertical axis. For example, the rotational transporting portion 530 may rotate with respect to a lower surface of the second vertical transporter 524 through an angle of about 90°. As with the other components above, the rotational transporting portion 530 may be actuated by pressurized air from the pressurized air supply unit 600.

The panel pickup portion 540 is coupled to the rotational transporting portion 530 to pick the display panels 10 up off of the respective panel holding units 100 after the driving elements 12 have been soldered thereon. The panel pickup portion 540 is disposed on a lower surface of the rotational transporting portion 530, and may have a clam-shell or claw-like shape for picking up the display panels 10, for example, by pressing against opposite sides of the display panels 10 to first grasp, and then pick them up from the underlying holding unit 100.

When two display panels 10 are disposed on the underlying panel holding unit 100, two panel pick-up portions 540 may be provided to pick up the two display panels 10 simultaneously. In general, the number of the panel pick-up portions 540 is the same as the number of the display panels 10 to be picked up from an underlying panel holding unit 100.

In order to transport the display panels 10 to the conveyor 50, the panel pick-up portions 540 of the transporting unit 500 first pick up the display panels 10 disposed on the panel holding unit 100, and the vertical transporting portions 520 then transport the picked-up display panels 10 in the vertical direction. Next, the horizontal transporting portion 510 transports the vertically transported display panels to the conveyor 50, and the rotational transporting portion 530 then rotates the horizontally transported display panels 10 in a horizontal plane through a selected angle to align them appropriately with the conveyor 50. The vertical transporting portion 520 then gently lowers the rotated display panels 10 onto the conveyor 50 for transportation to another processing station.

In accordance with the above description, the driving elements 12 are soldered to the respective flexible circuit boards of the display panels 10 using the automated soldering apparatus 700 of the present invention, thereby increasing both yield and productivity and decreasing manufacturing costs.

An exemplary embodiment of a method for soldering LED driving elements 12 to an LCD panel 10 using the exemplary soldering apparatus 700 of the invention is now described in detail in conjunction with FIGS. 1-6. With reference to the figures, in order to solder the driving elements 12 to the flexible circuit boards of the respective display panels 10, the display panels 10 are first loaded onto a panel holding unit 100 that is disposed on the rotating unit 200 at a selected radial distance from the center of rotation thereof. In particular, display panels 10 are transported by the conveyor 50 to the apparatus and then either manually or automatically loaded onto a panel holding unit 100 located in the loading region AR1 (see FIG. 2) of the apparatus. For example, two display panels 10 may be loaded onto the panel holding unit 100.

After the display panels 10 are loaded onto the panel holding unit 100, a start button (not illustrated) of the soldering apparatus 700 is pushed to begin the soldering operation. When the soldering apparatus begins operation, the cross arm 122 of the rotating part 120 of the holding body 100 of FIG. 3 is rotated downward toward the panels 10 by a torque provided by the rack-and-pinion mechanism of the torque generating part 130, and the clamps 124 of the rotating body 120 press respective ones of the display panels 10 against the main body 110. Alternatively, the holding parts 140 may be advanced in a horizontal direction toward the main body 110 so that the display panels 10 are securely fixed to the main body 110.

The rotating unit 200 is then rotated horizontally through a selected angle to rotate the display panels 10 that are fixed to the panel holding unit 100 to the first processing station, viz., 20 the buffer or fluxing region AR2 of the apparatus 700, as illustrated in FIG. 2. In the particular exemplary embodiment illustrated in the figures, the rotating unit 200 is thus rotated through an angle of 90°.

The flux applying unit 300, which is located in the buffer region AR2 of the apparatus, then applies flux to the leads of the driving elements of the display panels 10 that are rotated below it on the panel holding units 100. The end portions of the flux supplying parts 320 of the flux applying unit 300 are pressed against respective ones of the leads, and the flux applying unit 300 then dispenses an appropriate amount of the flux to the leads through openings in the respective ends thereof. As illustrated in the particular embodiment of FIG. 3, the flux supplying parts 320 are pen shaped.

When the flux has been appropriately applied to the leads of the driving elements 12 of the panels 10 at the buffering station AR2 of the apparatus 700, the rotating unit 200 is again rotated horizontally through a selected angle to rotate the panel holding unit 100 to the next processing station, viz., the soldering region AR3 (see FIG. 2) of the apparatus 700. In the particular embodiment illustrated, the rotating unit 200 is rotated horizontally through an angle of about 90° to position the panels 10 supported on the panel holding unit 100 below the soldering unit 400.

The driving elements 12 of the display panels 10 are then soldered using the soldering unit 400, as illustrated in FIG. 5. In particular, the solder supplying part 430 of the soldering unit 400 supplies a metered amount of solder to the leads or connecting terminals of the respective driving elements 12, and the soldering parts 420 of the soldering unit 400 then heat the solder to melt it such that the connecting terminals of the respective driving elements 12 are fixed to the flexible circuit board (not illustrated) of the respective display panels 10. In one particular exemplary embodiment, the soldering parts 420 heat the solder to a temperature of from between about 300° C. to about 380° C.

As illustrated in FIG. 5, the soldering unit 400 may include two soldering parts 420 arranged so as to solder the respective driving elements 12 of two display panels 10 simultaneously. Alternatively, to improve soldering accuracy, the soldering unit 400 may include only one soldering part 420, as described above, which effects soldering of respective ones of the two driving elements 12 sequentially. The positioning and soldering temperature of the soldering unit 400 are precisely controlled by an external control unit (not illustrated). For example, a computerized external system (not illustrated) can be used to precisely control the location and temperature of the soldering unit 400.

After the driving elements 12 of the respective panels 10 are soldered by the soldering unit 400, the rotating unit 200 is again rotated horizontally through a selected angle (in the embodiment illustrated, by 90°) to rotate the panel holding unit 100 to the pickup region AR4 of the apparatus 700, as illustrated in FIG. 2, where the display panels 10 are picked up off of the panel holding unit 100 and then transported to the conveyor 50 using the panel transporting unit 500.

In particular, after the soldering process, the panel holding unit 100 is rotated by the rotating unit 200 to the pickup region AR4, and the pickup portions 540 of the panel transporting unit 500 then grasp and pick up the respective display panels 10 from the panel holding unit 100, as illustrated in FIG. 5. The respective fingers of the panel pick-up portions 540 grasp opposite sides of respective ones of the display panels 10, then lift them up off of the panel holding unit 100 via the vertical transporting portion 520. In the particular exemplary embodiment illustrated in FIG. 6, the panel transporting unit 500 includes two panel pick-up portions 540 adapted to pick up two display panels 10 simultaneously. In general, the number of the panel pickup portions 540 is equal to the number of display panels 10 carried simultaneously on the panel holding unit 100.

The display panels 10 are then transported further in the vertical direction by the vertical transporting portion 520 of the panel transporting unit 500. As above, the vertical transporting portion 520 includes first and second vertical transporters 522 and 524. The first vertical transporter 522 transports the display panels 10 vertically through a first distance, and the second vertical transporter 524 transports them vertically through a second distance.

The vertically transported display panels 10 are then transported horizontally to the conveyor 50 using the horizontal transporting portion 510 of the panel transporting unit 500. After the display panels 10 are transported to the conveyor 50, the display panels 10 may be rotated in a horizontal plane through a selected angle using the rotational transporting portion 530 of the transporting unit 500. For example, the rotational transporting portion 530 may rotate the display panel 10 by about 90° so as to align them appropriately with the conveyor 50. For example, in the particular exemplary embodiment illustrated in FIG. 6, by rotating the rotational transporting portion 530 through an angle of 90°, the two display panels 10 are arranged serially in the longitudinal direction of the conveyor 50.

The rotated display panels 10 are then gently lowered onto the conveyor 50 using the vertical transporting portion 520 of the transporting unit so that the panels 10 are disposed on the conveyor 50 in the desired arrangement. In the exemplary embodiment illustrated in the figures, the conveyor 50 is disposed at a height that is lower than that of the rotating unit 200, so the vertical transporting portion is arranged so as to place the panels 10, i.e., on the conveyor 50, at a height that is different than that at which they were picked up, i.e., from the rotating unit 200.

After the display panels 10 are arranged on the conveyor 50, the panel transporting unit 500 returns to its original position at the pickup region AR4, ready for the next panel soldering operation.

As described above and illustrated in FIGS. 1-6, the LED driving elements 12 are not manually soldered to the flexible circuit boards of the display panels 10 in accordance with the prior art technique, but instead, are automatically soldered using the automated soldering apparatus 700 of the invention to substantially decrease the amount of labor and time needed to accomplish the task. Additionally, by using of the apparatus instead of the manual technique, the long term exposure of factory workers to lead is substantially decreased, thereby reducing potential job-related health risks.

By now, those of skill in this art will appreciate that many modifications, substitutions and variations can be made in and to the LCD LED driving element soldering methods and apparatus of the present invention without departing from its spirit and scope. In light of this, the scope of the present invention should not be limited to that of the particular embodiments illustrated and described herein, as they are only exemplary in nature, but instead, should be fully commensurate with that of the claims appended hereafter and their functional equivalents.

What is claimed is:

1. An apparatus for soldering a driving element of a display panel, comprising:
a holding unit for holding the display panel;
a rotating unit supporting the panel holding unit at an initial radial and angular position relative to a center of rotation of the rotating unit, and operable to rotate the holding unit in a horizontal plane about the center of rotation to selected angular positions relative to the initial angular position; and,
a soldering unit disposed above the rotating unit at the initial radial position and at a first angular position relative to the initial angular position of the panel holding unit, and operable to solder the driving element of the display panel held by the panel holding unit when the panel holding unit is rotated to the first angular position by the rotating unit.

2. The apparatus of claim 1, wherein the panel holding unit comprises:
a main body supporting the display panel;
an elongated rotating body for fixing the display panel to the main body in response to the application of a torque thereto; and,
a torque generating part for applying a torque to the rotating body.

3. The apparatus of claim 2, wherein the rotating body comprises:
a cross bar having a pair of extension arms extending perpendicularly from opposite ends thereof, each extension arm having an end supported on the main body for rotation of the cross bar toward and away from the main body in response to the application of the torque thereto; and,
a resilient clamp disposed on the cross arm for fixing the display panel to the main body.

4. The apparatus of claim 2, wherein:
the torque generating part is arranged to reciprocate longitudinally in a direction generally perpendicular to a long axis of the rotating part; and,
the rotating part is arranged to rotate up and down relative to the main body in response to the reciprocation of the torque generating part.

5. The soldering apparatus of claim 2, wherein the panel holding unit further comprises a holding part combined with the main body, the holding part being movable in a horizontal direction toward the main body so as to fix the panel thereto.

6. The apparatus of claim 1, wherein the soldering unit comprises:
a soldering body disposed above the rotating unit; and,
a soldering part protruding downward from a lower surface of the soldering body for soldering the driving element to a flexible circuit board of the panel.

7. The apparatus of claim 6, wherein the soldering unit further comprises a solder supplying part for supplying solder to the driving element through an end portion of the soldering part.

8. The apparatus of claim 1, further comprising a flux applying unit disposed above the rotating unit at the initial radial position and at a second angular position relative to the initial angular position of the panel holding unit, and operable to apply flux to the driving element of the display panel when the panel holding unit is rotated to the second angular position by the rotating unit.

9. The apparatus of claim 8, wherein the flux applying unit comprises:
a flux storage body disposed above the rotating unit; and,
a flux supplying part protruding downwardly from a lower surface of the flux storage body for applying the flux to the driving element.

10. The apparatus of claim 9, wherein the flux applying part is shaped like a pen.

11. The apparatus of claim 1, further comprising a panel transporting unit disposed above the rotating unit at the initial radial position and at a third angular position relative to the initial angular position of the panel holding unit, and operable to transport the display panel to a conveyor.

12. The apparatus of claim 11, wherein the panel transporting unit comprises:
a horizontal transporting portion for transporting the display panel in a horizontal direction;
a vertical transporting portion coupled to the horizontal transporting portion for transport the display panel in a vertical direction; and,
a pickup portion disposed below the vertical transporting portion for grasping and picking up the display panel from the panel holding unit.

13. The apparatus of claim 12, wherein the panel transporting unit further comprises a rotational transporting portion interposed between the vertical transporting portion and the panel pickup portion for rotating the display panel through a selected angle in a horizontal plane.

14. The apparatus of claim 12, wherein the vertical transporting portion comprises:
a first vertical transporter coupled to the horizontal transporting portion for transporting the display panel a first distance in the vertical direction; and,
a second vertical transporter coupled to the first vertical transporter for transporting the display panel a second distance in the vertical direction.

15. The apparatus of claim 1, further comprising a pressurized air supplying unit for supplying pressurized air to the panel holding unit to hold the display panel.

16. The apparatus of claim 15, wherein the pressurized air supplying unit is disposed at the center of rotation of the rotating unit.

17. The apparatus of claim 1, wherein the rotating unit rotates in angular increments of about 90° each.

18. The apparatus of claim 1, wherein four panel holding units are arranged on the rotating unit in a substantially square pattern.

19. A method of soldering a driving element of a display panel, the method comprising:
loading the display panel on a panel holding unit;
supporting the panel holding unit on an upper surface of a rotating unit;
rotating the panel holding unit with the rotating unit in a horizontal plane about a center of rotation of the rotating unit and to a position below a soldering unit; and,
soldering the driving element to the display panel with the soldering unit.

20. The method of claim 19, wherein soldering the driving element comprises:
rotating the panel holding unit with the rotating unit in a horizontal plane about the center of rotation of the rotating unit and to a position below a flux applying unit; and,
applying flux to the driving element with the flux applying unit.

21. The method of claim 19, further comprising transporting the soldered display panel to a conveyor.

22. The method of claim 21, wherein transporting the soldered display panel to a conveyor comprises:
picking up the soldered display panel from the panel holding unit;
transporting the picked up display panel in a vertical direction;
transporting the vertically transported display panel in a horizontal direction; and,
disposing the horizontally transported display panel on the conveyor.

23. The method of claim 19, wherein the panel holding unit is rotated in a horizontal plane through an angle of about 90°.
